(19) United States
(12) Patent Application Publication
(10) Pub. No.: US 2009/0166833 A1
(43) Pub. Date: Jul. 2, 2009

(54) SEMICONDUCTOR UNIT WHICH INCLUDES MULTIPLE CHIP PACKAGES INTEGRATED TOGETHER

(75) Inventors: STEVEN WEBSTER, Tu-Cheng (TW); YING-CHENG WU, Tu-Cheng (TW); MENG-LUNG YU, Tu-Cheng (TW); SHIH-MIN LO, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/061,914

(22) Filed: Apr. 3, 2008

(30) Foreign Application Priority Data
Dec. 28, 2007 (CN) 200710203519.X

(51) Int. Cl. H01L 23/02; H01L 21/00

(52) U.S. Cl. 257/685; 438/113; 257/E23.18; 257/E21.001

(57) ABSTRACT

A semiconductor unit includes an interface plate, a supporting plate integrally formed with the interface plate, two chip packages positioned at opposite sides of the supporting plate, and leading traces running in the interface plate and the supporting plate, connected with the chip packages respectively.

### BACKGROUND

1. Technical Field

The present invention relates to semiconductor units and, particularly, to a semiconductor unit which includes multiple chip packages integrated together.

2. Description of Related Art

In accordance with the trend of miniaturizing electronic apparatuses, attempts are being made to achieve high density semiconductor units. Therefore, the package itself is being more and more miniaturized, and attempts are being made to pack more than one chip into one package. Generally, the chips are stacked on each other one by one and testing of the package is done after assembly. If one chip in the package is faulty then the whole package must be considered faulty.

What is needed, therefore, is a semiconductor unit which can overcome the above described problems.

### SUMMARY

In accordance with a present embodiment, a semiconductor unit includes an interface plate, a supporting plate integrally formed with the interface plate, two chip packages positioned at opposite sides of the supporting plate, and leading traces in the interface plate and the supporting plate, connected with the chip packages respectively.

Other advantages and novel features will be drawn from the following detailed description of at least one preferred embodiment, when considered in conjunction with the attached drawings.

### BRIEF DESCRIPTION OF THE DRAWINGS

Many aspects of the present semiconductor unit can be better understood with reference to the following drawings. The components in the drawings are not necessarily drawn to scale, the emphasis instead being placed upon clearly illustrating the principles of the present semiconductor unit. Moreover, in the drawings, like reference numerals designate corresponding parts throughout the several views.

FIG. 1 is a schematic, cross-sectional view of a semiconductor unit, according to a first exemplary embodiment.

FIG. 2 is a schematic, cross-sectional view of a combination of a substrate and a plurality of chip packages before being sawed into semiconductor units as shown in FIG. 1.

FIG. 3 is a schematic, cross-sectional view of a semiconductor unit, according to a second exemplary embodiment.

FIG. 4 is a schematic, cross-sectional view of a combination of a substrate and a plurality of chip packages before being sawed into semiconductor units as shown in FIG. 3.

### DETAILED DESCRIPTION OF THE EMBODIMENTS

Embodiments of the present semiconductor unit will now be described in detail below with reference to the drawings.

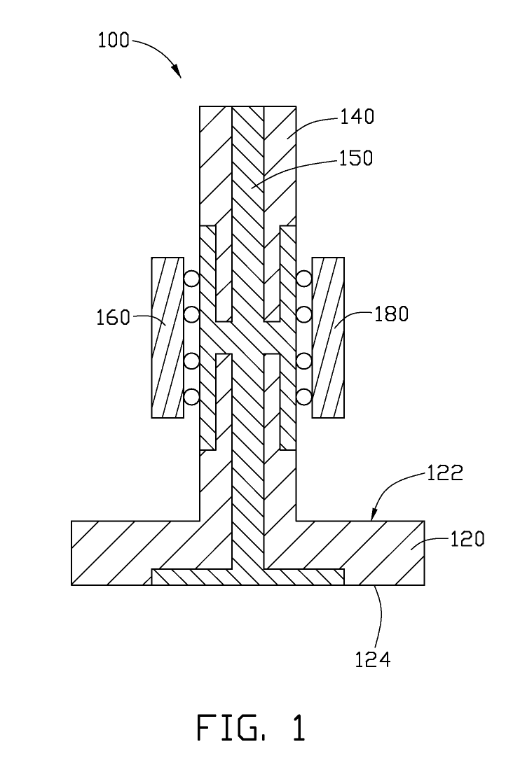

Referring to FIG. 1, a semiconductor unit 100 in accordance with a present first embodiment is illustrated. The semiconductor unit 100 comprises an interface plate 120, a supporting plate 140, leading traces 150, and two chip packages 160, 180. The interface plate 120 comprises a first surface 122 and a second surface 124 opposite to the first surface 122. The interface plate 120 is configured for positioning the semiconductor unit 100 somewhere, such as on a socket (not shown). The supporting plate 140 is integrally formed with the first side 122 of the interface plate 120. The supporting plate 140 and the interface plate 120 cooperatively form an inverted T-shaped module as shown in FIG. 1. Each of the chip packages 160, 180 is an individually packed functional module. The chip packages 160, 180 are positioned at two sides of the supporting plate 140, and electrically connected with the leading traces 150 respectively. The leading traces 150 run in the interface plate 120 and the supporting plate 140, and are configured at the second surface 124 of the interface plate 120 for being electrically connected with other components (not shown), so that the semiconductor unit 100 can communicate with the components via the leading traces 150.

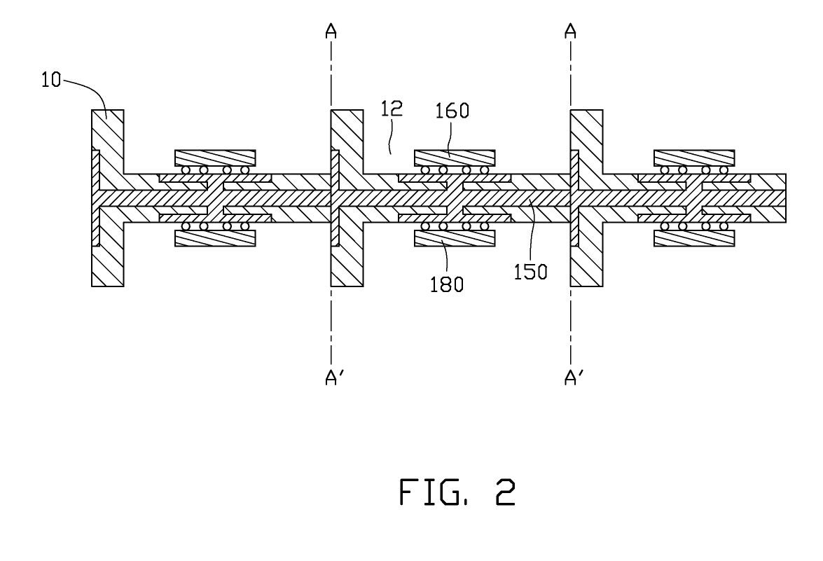

FIG. 2 illustrates a combination of a substrate 10 and a plurality of chip packages 160, 180 before being sawed into semiconductor units 100 as shown in FIG. 1. For manufacturing the semiconductor unit 100, an integrally formed rectangular substrate 10 is provided. The substrate 10 can be made of, for example, epoxy, polyimide, or Teflon, and defines a plurality of rectangular cavities 12 therein at uniform intervals. The cavities 12 are symmetrically located at two opposite sides of the substrate 10. The leading traces 150 run through the substrate 10. The chip packages 160, 180 are respectively received in opposing cavities 12, and electronically connected to the leading traces 150. The substrate 10 is then sawed into T-shaped semiconductor units 100, along A-A′ lines as shown in FIG. 2.

In this embodiment, the chip packages 160, 180 are first quality checked, and then simultaneously positioned in the cavities 12, instead of one after another. After the chip packages 160, 180 are combined to the substrate 10, a quality check is performed on the combination of the chip packages 160, 180 and the substrate 10 to further ensure that the chip packages 160, 180 are properly connected to the substrate 10. In this way, manufacturing efficiency and quality rate of the semiconductor units 100 are both enhanced.

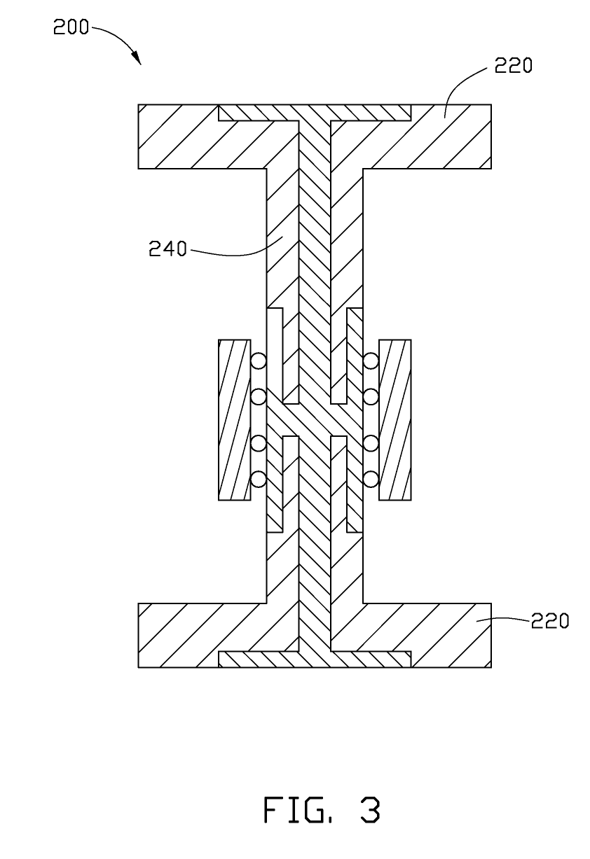

FIG. 3 illustrates a semiconductor unit 200 in accordance with a second embodiment. The semiconductor unit 200 is similar to the semiconductor unit 100. However, the semiconductor unit 200 comprises an additional interface plate 220 at a free end of its supporting plate 240 to form an H-shaped module. Other features of the semiconductor unit 200 can be referenced from the description of the semiconductor unit 100.

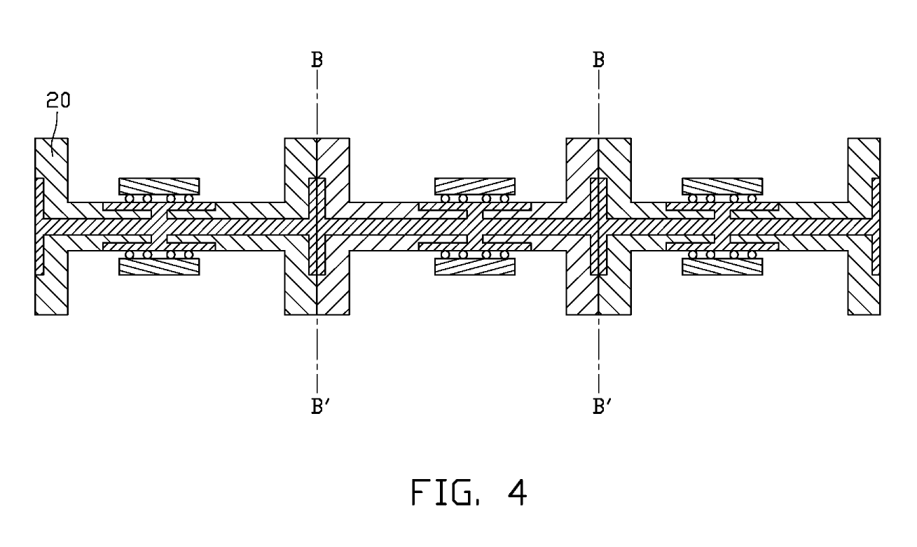

FIG. 4 illustrates a combination of a substrate 20 and a plurality of chip packages before being sawed into semiconductor units 200 as shown in FIG. 3. The substrate 20 is similar to the substrate 10, but can be sawed into H-shaped semiconductor units 200 along lines B-B′ as shown in FIG. 4.

It will be understood that the above particular embodiments and methods are shown and described by way of illustration only. The principles and features of the present invention may be employed in various and numerous embodiments thereof without departing from the scope of the invention as claimed. The above-described embodiments illustrate the scope of the invention but do not restrict the scope of the invention.

What is claimed is:

1. A semiconductor unit comprising:
an interface plate;
a supporting plate integrally formed with the interface plate;
two chip packages positioned at opposite sides of the supporting plate; and
leading traces in the interface plate and the supporting plate, connected with the chip packages respectively.

2. The semiconductor unit as claimed in claim 1, wherein the interface plate and the supporting plate cooperatively form a T-shaped module.

3. The semiconductor unit as claimed in claim 1, wherein the semiconductor unit comprises an additional interface plate, and the interface plates and the supporting plate cooperatively form an H-shaped module.

4. The semiconductor unit as claimed in claim 1, wherein the supporting plate is perpendicular to the interface plate.

5. A method of manufacturing semiconductor units, comprising:
providing an integrally formed substrate with a plurality of cavities defined at two sides thereof with leading traces running therethrough;
placing a plurality of chip packages into the cavities and electrically connecting the chip packages with the leading traces; and
sawing the substrate into a plurality of semiconductor units each comprising two chip packages.

6. The method as claimed in claim 5, wherein the cavities are symmetrically located at opposite sides of the substrate.

7. The method as claimed in claim 5, wherein the cavities are placed at uniform intervals.

8. The method as claimed in claim 5, wherein each semiconductor unit is a T-shaped module comprising an interface plate and a supporting plate with the chip packages positioned thereon.

9. The method as claimed in claim 8, wherein the supporting plate is perpendicular to the interface plate.

10. The method as claimed in claim 5, wherein each semiconductor unit is an H-shaped module comprising two interface plates and a supporting plate with the chip packages positioned thereon.

11. The method as claimed in claim 10, wherein the supporting plate is located between and perpendicular to the interface plates.
